(19) United States
(12) Patent Application Publication
(10) Pub. No.: US 2024/0079275 A1
(43) Pub. Date: Mar. 7, 2024

(54) METHOD OF MANUFACTURING SILICON CARBIDE SEMICONDUCTOR DEVICE

(71) Applicant: FUJI ELECTRIC CO., LTD., Kawasaki-shi (JP)

(72) Inventors: Takashi TSUJI, Matsumoto-city (JP); Yuichi ONOZAWA, Matsumoto-city (JP); Naoto FUJISHIMA, Matsumoto-city (JP); Linhua HUANG, Kowloon (HK); Johnny Kin On SIN, Kowloon (HK)

(73) Assignee: FUJI ELECTRIC CO., LTD., Kawasaki-shi (JP)

(21) Appl. No.: 18/308,044

(22) Filed: Apr. 27, 2023

Related U.S. Application Data
(63) Continuation of application No. PCT/JP2021/037253, filed on Oct. 7, 2021.

(51) Int. Cl. H01L 21/8234; H01L 21/02; H01L 21/04

(52) U.S. Cl. CPC H01L 21/823462; H01L 21/02164; H01L 21/02178; H01L 21/02236; H01L 21/0445

(57) ABSTRACT

A gate insulating film has a multilayer structure including a SiO₂ film, a LaAlO₃ film, and an Al₂O₃ film that are sequentially stacked, relative permittivity of the gate insulating film being optimized by the LaAlO₃ film. In forming the LaAlO₃ film constituting the gate insulating film, a La₂O₃ film and an Al₂O₃ film are alternately deposited repeatedly using an ALD method. The La₂O₃ film is deposited first, whereby during a POA performed thereafter, a sub-oxide of the surface of the SiO₂ film is removed by a cleaning effect of lanthanum atoms in the La₂O₃ film. A temperature of the POA is suitably set in a range from 700 degrees C. to less than 900 degrees C.

### CROSS REFERENCE TO RELATED APPLICATIONS

This non-provisional application is a continuation of International Application PCT/JP2021/037253, filed on Oct. 7, 2021, and designating the U.S., the entire contents of which are incorporated herein by reference.

### BACKGROUND OF THE INVENTION

### 1. Field of the Invention

Embodiments of the invention relate to a method of manufacturing silicon carbide semiconductor device.

### 2. Description of the Related Art

Conventionally, in a vertical MOSFET (metal oxide semiconductor field effect transistor: MOS-type field effect transistor including insulated gates having a three-layer structure including a metal, an oxide film, and a semiconductor) having a trench gate structure, configuration is such that bottoms of gate trenches that are each embedded with a gate electrode via a gate insulating film are closer to an n⁺-type substrate region and therefore, when reverse bias is applied between a gate and source during an OFF state, and positive high voltage is applied between a drain and a source during an OFF state, electric field concentrates at the gate insulating films at the bottoms of the gate trenches and dielectric breakdown easily occurs.

In an instance in which silicon carbide (SiC) is used as a semiconductor material, a critical electric field strength is at least 10 times that in an instance in which silicon (Si) is used as a semiconductor material and therefore, an electric field at the gate insulating films of the gate trenches also increases. Thus, in a vertical SiC-MOSFET having a trench gate structure using silicon carbide as a semiconductor material, a commonly known structure thereof includes p⁺-type regions selectively provided in an n⁻-type drift region, at deep positions closer to an n⁺-type substrate region than are the bottoms of the gate trenches, whereby the electric field applied to the gate insulating films at the bottoms of the gate trenches is mitigated.

A structure of a conventional silicon carbide semiconductor device is described. FIG. 13 is a cross-sectional view of the structure of a conventional silicon carbide semiconductor device. A conventional silicon carbide semiconductor device 110 depicted in FIG. 13 is a vertical SiC-MOSFET having a trench gate structure in which a gate trench 107 formed in a semiconductor substrate 120 containing silicon carbide are embedded, respectively, with a gate electrode 109 via a gate insulating film 108. The gate trench 107 penetrates through an n⁺-type source region 105 and a p-type base region 104 from a front surface of the semiconductor substrate 120 and reach a predetermine depth.

Between an n⁻-type drift region 103 and the p-type base region 104, at positions closer to an n⁺-type substrate region 101 than are the gate trench 107, p⁺-type regions 131, 132 and n-type current spreading regions 133 are each selectively provided. The p⁺-type regions 131, 132 and the n-type current spreading regions 133 are diffused regions formed by ion implantation in an n⁻-type epitaxial layer 123. A portion of the n⁻-type epitaxial layer 123 excluding the p⁺-type regions 131, 132 and the n-type current spreading regions 133 is the n⁻-type drift region 103.

The p⁺-type regions 131, 132 have a function of mitigating electric field applied to the gate insulating film 108 at a bottom of the gate trench 107. The p⁺-type region 131 is disposed facing the bottom of the gate trench 107 in a depth direction, separate from the p-type base region 104. Between the gate trench 107 and gate trenches adjacent thereto, the p⁺-type regions 132 are respectively disposed in contact with the p-type base region 104 and separate from said gate trench 107 and the p⁺-type region 131, the p⁺-type regions 132 reaching positions a same depth toward the n⁺-type substrate region 101 as a depth of the p⁺-type regions 131.

The n-type current spreading regions 133 have a function of reducing carrier spreading resistance. Reference numerals 121, 122, 123, and 124 are, respectively, an n⁺-type starting substrate 121 configuring the semiconductor substrate 120 and epitaxial layers, respectively, constituting the n⁺-type substrate region 101, an n-type buffer region 102, the n⁻-type drift region 103, and the p-type base region 104. Reference numerals 106, 111, and 115 are p⁺⁺-type contact regions, an interlayer insulating film, and a drain electrode. Reference numerals 112, 113, and 114 are metal films configuring a source electrode.

In the conventional silicon carbide semiconductor device 110 depicted in FIG. 13, when reverse bias is applied between the gate and source during the OFF state, and positive high voltage is applied between a drain and a source during an OFF state, electric field applied to the gate insulating film 108 at the bottom of the gate trench 107 is mitigated by the p+-type regions 131, whereby design is such that reliability of the gate insulating film 108 is enhanced and a lifespan of the gate insulating film 108 is sufficiently long.

As a conventional silicon carbide semiconductor device, a SiC-MOSFET has been proposed in which gate insulating films have a multilayer structure including sequentially a lower layer film constituted by a silicon dioxide (SiO₂) film and an upper layer film constituted by a high permittivity (high-k) film including at least any one of an aluminum oxide (Al₂O₃), an aluminum oxynitride (AlOxNy), and a hafnium oxide (HfxOy) (for example, refer to Japanese Laid-Open Patent Publication No. 2016-157976). In Japanese Laid-Open Patent Publication No. 2016-157976, a thickness of the SiO₂ film is reduced, whereby mobile ions in the gate insulating films are reduced and high-temperature operation is stabilized.

As a conventional semiconductor device, a transistor has been proposed in which a dielectric film functioning as gate insulating films is a lanthanum aluminum oxide (LaAlO₃) film (for example, refer to Published Japanese-Translation of PCT Application, Publication No. 2004-533108). Published Japanese-Translation of PCT Application, Publication No. 2004-533108 discloses that the LaAlO₃ film of an amorphous structure deposited using an atomic layer chemical vapor deposition (ALCVD) method is useful for optimizing relative permittivity of the gate insulating films and for reducing gate leak current (leak current passing through the gate insulating films).

As another conventional silicon carbide semiconductor device, a MOS-type semiconductor device has been proposed in which gate insulating films have a multilayer structure in which a silicon oxynitride (SiOxNy) film and a hafnium oxide (HfO₂) film are sequentially sacked (for example, refer to Cheong, K. Y., 7 others, “Improved electronic performance of HfO₂/SiO₂ stacking gate dielectric on 4H SiC”, IEEE Transactions On Electron Devices, (USA), IEEE: Institute of Electrical and Electronics Engineers, December 2007, Vol. 54, No. 12, pp. 3409-3413). In Cheong, K. Y., et al, “Improved electronic performance of HfO₂/SiO₂ stacking gate dielectric on 4H SiC”, gate leak current is reduced by the SiOxNy film, and interface state density (Dᵢₜ) of interfaces between the gate insulating films and a semiconductor substrate is reduced by a HfO₂ film having a high permittivity and deposited using an atomic layer deposition (ALD) method.

As another conventional silicon carbide semiconductor device, a MOS-type semiconductor device has been proposed in which gate insulating films have a multilayer structure in which a lanthanum silicate (LaSiOx) film, and a SiO₂ film deposited using an ALD method are sequentially stacked (for example, refer to Yang, X., 2 others, “High mobility 4H—SiC lateral MOSFETs using lanthanum silicate and atomic layer deposited SiO₂”, IEEE Electron Device Letters, (USA), IEEE: Institute of Electrical and Electronics Engineers, April 2015, Vol. 36, No. 4, pp. 312-314, and Jayanti, S., 3 others, “Technique to improve performance of Al₂O₃ interpoly dielectric using a La₂O₃ interface scavenging layer for floating gate memory structures”, Applied Physics Letters, (USA), American Institute of Physics, 2010, No. 96, 092905). Yang, X. and Jayanti, S disclose that during formation of the LaSiOx film, a sub-oxide (SiOx) of a semiconductor substrate surface reacts with lanthanum atoms in a lanthanum oxide (La₂O₃) film and is removed, whereby interface state density of interfaces between gate insulating films and a semiconductor substrate is reduced.

As another conventional silicon carbide semiconductor device, a MOS-type semiconductor device has been proposed in which gate insulating films have a multilayer structure in which a SiO₂ film and an aluminum oxynitride (AlON) film are sequentially stacked (for example, refer to Hosoi, T., 11 others, “Performance and reliability improvement in SiC power MOSFETs by implementing AlON high-k gate dielectrics”, IEDM: International Electron Devices Meeting, (USA), IEEE: Institute of Electrical and Electronics Engineers, 2012, pp. 7.4.1-7.4.4). In Hosoi, T., et al, “Performance and reliability improvement in SiC power MOSFETs by implementing AlON high-k gate dielectrics”, a ratio of a thickness of the AlON film to a thickness of the SiO₂ film and a nitrogen content of the AlON film are optimized, increasing the performance and reliability of the silicon carbide semiconductor device. Further, Hosoi, T., et al discloses that the thickness of the SiO₂ film is set to be at least 5 nm, whereby gate leak current is suppressed.

Further, it has been disclosed that lanthanum aluminate (LaAlO₃) having a high relative permittivity compared to SiOxNy and a bandgap of 5.6 eV may be used as an insulating material of gate insulating films (for example, refer to Miotti, L., 8 others, “Atomic transport in LaAlO₃ films on Si induced by thermal annealing”, Electrochemical and Solid-State Letters, (USA), The Electrochemical Society, April 2006, Vol. 9, No. 6, pp. F49-F52). Miotti, L., et al discloses that gate insulating films have a structure in which an LaAlO₃ film and an Al₂O₃ film are sequentially deposited on a semiconductor substrate (Si substrate), whereby during annealing, out-diffusion of La atoms and Al atoms in the LaAlO₃ film does not occur. Further, it is disclosed that this annealing temperature is set to be at most 800 degrees C., whereby migration of Si atoms in the semiconductor substrate is suppressed.

In forming the LaAlO₃ film as gate insulating films, it is disclosed that annealing conditions and a deposition method for the LaAlO₃ film are optimized, whereby electrical characteristics of the LaAlO₃ film are improved (for example, refer to Park, B. E., 1 other, “Formation of films on Si (100) substrates using molecular beam deposition”, Applied Physics Letters), (USA), American Institute of Physics, February 2003, Vol. 82, No. 8, pp. 1197-1199). Park, B. E., et al, discloses that under a nitrogen (N₂) atmosphere, the LaAlO₃ film is annealed by a temperature of 800 degrees C., whereby hysteresis of a C-V curve of electrostatic capacitance C and gate voltage V g of the LaAlO₃ film decreases and gate leak current density is reduced.

It has been disclosed that a cap film containing Al₂O₃ is formed on a LaAlO₃ film, whereby the LaAlO₃ film is not exposed to air and the LaAlO₃ film may be protected from moisture absorption (H₂O absorption) (for example, refer to Swerts, J., 7 others, “Stabilization of ambient sensitive atomic layer deposited lanthanum aluminates by annealing and in situ capping”, Applied Physics Letters, (USA), American Institute of Physics, March 2011, No. 98, 102904). Swerts, J., et al discloses that the LaAlO₃ film is covered by an Al₂O₃ film, whereby the LaAlO₃ film is protected from moisture absorption and contamination of the LaAlO₃ film during a subsequent annealing treatment (absorption of contaminants in an annealing furnace) is prevented.

### SUMMARY OF THE INVENTION

According to an embodiment of the invention, a method of manufacturing a silicon carbide semiconductor device including an insulated gate having a three-layer structure including a gate electrode, a gate insulating film having a multilayer structure including a LaAlO₃ film, and a semiconductor substrate containing silicon carbide, the method includes: forming the gate insulating film on a surface of the semiconductor substrate, the forming the gate insulating film including repeatedly depositing a La₂O₃ atomic layer film alternating with an Al₂O₃ atomic layer film, wherein the La₂O₃ atomic layer film is deposited first, using an atomic layer deposition method, as a deposition process, thereby forming the LaAlO₃ film as the gate insulating film, and performing a heat treatment at a temperature that is less than 900 degrees C. after the deposition process; and forming the gate electrode facing the semiconductor substrate with the gate insulating film intervening therebetween.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a structure of a silicon carbide semiconductor device according to a first embodiment.

FIG. 2 is an enlarged view of a vicinity of a MOS gate in FIG. 1.

FIG. 3 is a flowchart of an outline of the method of manufacturing the silicon carbide semiconductor device according to the first embodiment.

FIG. 4 is a cross-sectional view of a structure of a silicon carbide semiconductor device according to a second embodiment.

FIG. 5 is a cross-sectional view schematically depicting a cross-section of a structure of a MOS capacitor of experiment examples.

FIG. 6 is a cross-sectional view schematically depicting a state of a gate electrode and a gate insulating film of the experiment examples during deposition thereof.

FIG. 7 is a table showing configurations of the gate insulating films of the experiment examples.

FIG. 8 is a characteristics diagram depicting, for the experiment examples, relationships between C-V characteristics and a temperature of a POA at step S8 in FIG. 3.

FIG. 9A is a characteristics diagram depicting, for a first experiment example, relationships between C-V characteristics and the temperature of the POA at step S8 in FIG. 3.

FIG. 9B is a characteristics diagram depicting, for a second experiment example, relationships between C-V characteristics and the temperature of the POA at step S8 in FIG. 3.

FIG. 9C is a characteristics diagram depicting, for a third experiment example, relationships between C-V characteristics and the temperature of the POA at step S8 in FIG. 3.

FIG. 10 is a characteristics diagram depicting relationships between the temperature of the POA at step S8 in FIG. 3 and interface state density of an interface between the gate insulating film and the semiconductor substrate for the experiment examples.

FIG. 11 is a characteristics diagram depicting relationships between dielectric breakdown electric field strength of the experiment examples and the temperature of the POA at step S8 in FIG. 3.

FIG. 12 is a characteristics diagram depicting dielectric breakdown electric field strength of examples.

FIG. 13 is a cross-sectional view of a structure of a conventional silicon carbide semiconductor device.

### DETAILED DESCRIPTION OF THE INVENTION

First, problems associated with the conventional techniques are discussed. Even in an instance in which silicon carbide is used as a semiconductor material, similarly to an instance in which silicon is used as a semiconductor material, it is actually better for the p⁺-type regions 131, 132 (refer to FIG. 13) to not be provided near the bottom of the gate trench 107. A reason for this is that the process for forming the p⁺-type regions 131, 132 is not performed, whereby the manufacturing process may be simplified and manufacturing cost may be reduced. Nonetheless, when configuration simply omits the p⁺-type regions 131, 132, high electric field is applied to the gate insulating film 108 at the bottom of the gate trench 107 and therefore, various problems arise such as decreased reliability of the gate insulating film 108, shorter lifespan of the gate insulating film 108 until dielectric breakdown occurs, etc.

Embodiments of a method of manufacturing a silicon carbide semiconductor device according to the present invention is described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −, and represents one example. In the description of the embodiments below and the accompanying drawings, main portions that are identical will be given the same reference numerals and will not be repeatedly described.

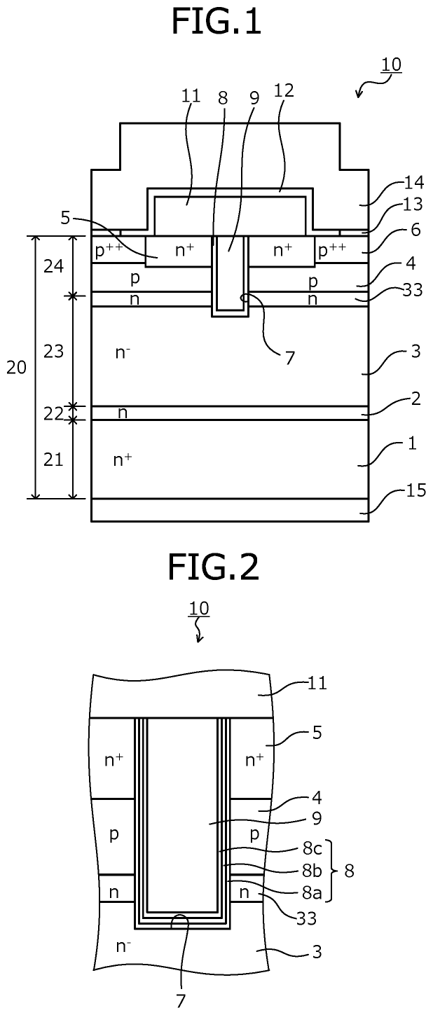

A structure of a silicon carbide semiconductor device according to a first embodiment is described. FIG. 1 is a cross-sectional view of the structure of the silicon carbide semiconductor device according to the first embodiment. FIG. 2 is an enlarged view of a vicinity of a MOS gate in FIG. 1. A silicon carbide semiconductor device 10 according to the first embodiment depicted in FIGS. 1 and 2 is a vertical SiC-MOSFET having, in an active region, a trench gate structure on a front side of a semiconductor substrate 20 containing silicon carbide (SiC). The active region is a region through which a main current (drift current) flows when the MOSFET is in an ON state.

An edge termination region (not depicted) is a region between the active region and an end of the semiconductor substrate 20, having a function of mitigating electric field of the front side of the semiconductor substrate 20 and sustaining a breakdown voltage. In the edge termination region, a voltage withstanding structure such as a field limiting ring (FLR), junction termination extension (JTE) structure, or guard ring (not depicted) is disposed. The breakdown voltage is a voltage limit at which no erroneous operation or destruction of the silicon carbide semiconductor device 10 occurs.

The semiconductor substrate 20 is formed by sequentially forming epitaxial layers 22, 23, and 24 constituting an n-type buffer region 2, an n⁻-type drift region 3, and a p-type base region 4, on a front surface of an n⁺-type starting substrate 21 containing silicon carbide. A main surface of the semiconductor substrate 20 having the p-type epitaxial layer 24 is assumed as the front surface while another main surface of the semiconductor substrate 20 having the n⁺-type starting substrate 21 is assumed as a back surface. The n⁻-type starting substrate 21 is an n⁺-type substrate region 1. The n-type buffer region 2 is provided between the n⁺-type substrate region 1 and the n⁻-type drift region 3 and is in contact with these regions.

The n-type buffer region 2 has a function of preventing electric field from reaching the n⁺-type starting substrate 21, the electric field being generated during reverse bias. In an instance in which the n-type buffer region 2 is not provided, the n⁻-type epitaxial layer 23 constituting the n⁻-type drift region 3 is epitaxially grown on the front surface of the n⁺-type starting substrate 21.

The n⁻-type drift region 3 is provided between the p-type base region 4 and the n-type buffer region 2 and is in contact with these regions. In the n⁻-type epitaxial layer 23, regions like the p⁺-type regions 131, 132 of the conventional structure (refer to FIG. 13) are not provided. Even when a region like the p⁺-type region 131 of the conventional structure are omitted and electric field is applied to a gate insulating film at a bottom of a trench 7, when a multilayer structure of a later-described gate insulating film 8 of the present embodiment is used, reliability of the gate insulating film 8 may be ensured.

The n-type current spreading region 33 is a current spreading layer to uniformly pass channel current through an entire area of the n⁻-type epitaxial layer 23, the channel current flowing from the n⁺-type source region 5, through channels (n-type inversion layers) formed in the p-type base region 4, along sidewalls of the trench 7 to the n⁻-type epitaxial layer 23 (the n⁻-type drift region 3) during an ON state of the MOSFET; provision of the n-type current spreading region 33 can lead to reduction of ON resistance. The p-type base region 4 is a portion of the p-type epitaxial layer 24 excluding the later-described n⁺-type source region 5 and later-described p⁺⁺-type contact regions 6. The p-type base region 4 is provided between the front surface of the semiconductor substrate 20 and the n⁻-type drift region 3.

The trench gate structure is configured by the p-type base region 4, the n⁺-type source region 5, the p⁺⁺-type contact regions 6, and a MOS gate including the later-described trench (gate trench) 7, the gate insulating film 8, and a gate electrode 9. The n⁺-type source region 5 and the p⁺⁺-type contact regions 6 are diffused regions formed by ion implantation in the p-type epitaxial layer 24. The n⁺-type source region 5 and the p⁺⁺-type contact regions 6 are each selectively provided between the front surface of the semiconductor substrate 20 and the p-type base region 4.

The n⁺-type source region 5 and the p⁺⁺-type contact regions 6 are in contact with the p-type base region 4 and are exposed at the front surface of the semiconductor substrate 20, in contact holes of a later-described interlayer insulating film 11. Being exposed at the front surface of the semiconductor substrate 20 means being in contact with later-described ohmic electrodes 13 through the contact holes of the interlayer insulating film 11. The p⁺⁺-type contact regions 6 may be omitted. In an instance in which the p⁺⁺-type contact regions 6 are omitted, instead of the p⁺⁺-type contact regions 6, the p-type base region 4 is exposed at the front surface of the semiconductor substrate 20.

The trench 7 penetrates through the n⁺-type source region 5 and the p-type base region 4 and reaches the n⁻-type drift region 3. Along an inner wall of the trench 7, the gate insulating film 8 is provided on the inner wall (surface of the semiconductor substrate 20) of the trench 7. The gate insulating film 8 is a multilayer structure including a silicon dioxide (SiO₂) film 8a, a lanthanum aluminum oxide (LaAlO₃, so-called LAO) film 8b, and an aluminum oxide (Al₂O₃) film 8c sequentially stacked on one another. The SiO₂ film 8a has a function of reducing an interface state density (Dᵢₜ) of an interface between the gate insulating film 8 and the semiconductor substrate 20.

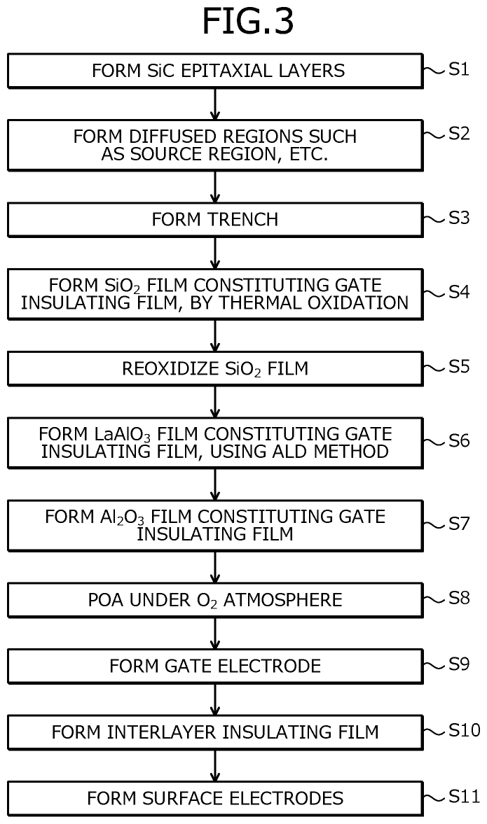

The SiO₂ film 8a, for example, is formed by thermally oxidizing an entire surface of the inner wall of the trench 7 and is in contact with the semiconductor substrate 20 at the inner wall of the trench 7. The SiO₂ film 8a, for example, may be reoxidized by annealing (post-oxidation annealing (POA)) under a gas atmosphere of nitrogen monoxide (NO) or nitrous oxide (N₂O) (refer to step S5 of later-described FIG. 3). By reoxidation of the SiO₂ film 8a, an interface state of the gate insulating film 8 and the semiconductor substrate 20 is passivated. A thickness of the SiO₂ film 8a, for example, may be in a range from about 5 nm to 10 nm.

It is preferable for a sub-oxide (SiOx, where x is less than 2) to be removed from the interface between the SiO₂ film 8a and the LaAlO₃ film 8b by a later-described cleaning (scavenging) effect. The sub-oxide is an oxide film that has inferior film quality and that stoichiometrically is not SiO₂, having non-oxygen atoms forming some of the four bonds with Si; more specifically, the sub-oxide is a natural oxide film. The gate insulating film 8 does not contain a sub-oxide and therefore, the interface state density of the interface between the gate insulating film 8 and the semiconductor substrate 20 may be reduced.

The LaAlO₃ film 8b is a high permittivity (high-k) film having an amorphous structure, deposited on a surface of the SiO₂ film 8a using an atomic layer deposition (ALD) method (refer to step S6 in later-described FIG. 3). Relative permittivity k of the LaAlO₃ film 8b is higher than that of the SiO₂ film 8a and, for example, is in a range from about 13 to 27. The relative permittivity k of the gate insulating film 8 is optimized by the LaAlO₃ film 8b and can mitigate electric field applied to the gate insulating film 8 at the bottom of the trench 7 when reverse bias is applied between the gate and source.

Further, the gate insulating film 8 includes the LaAlO₃ film 8b having a relative permittivity k that is higher than that of the SiO₂ film 8a, thereby enabling gate capacitance (parasitic capacitance formed between the source and gate by electrostatic capacitance of the gate insulating film 8) to be increased, whereby gate leak current (leak current flowing through the gate insulating film 8 when the MOSFET is OFF) may be reduced. A thickness of the LaAlO₃ film 8b, for example, is at least 20 nm, which obtains an effect by the LaAlO₃ film 8b, and preferably, for example, may be in a range from about 40 nm to 50 nm.

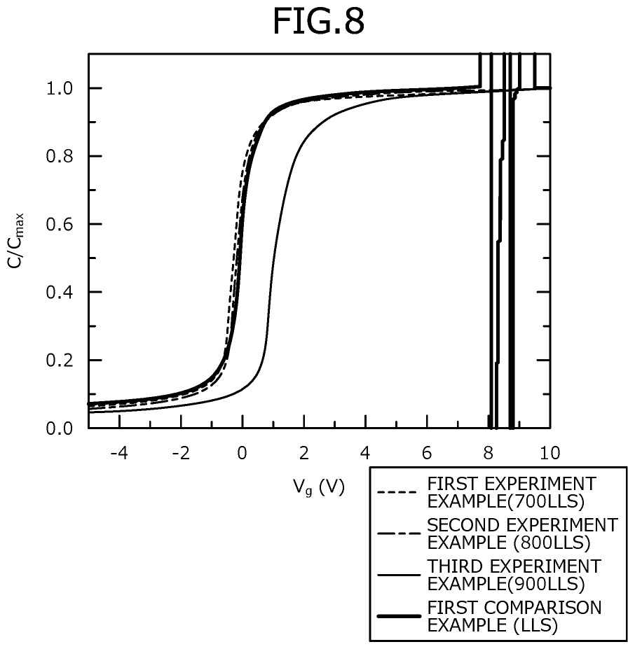

Further, preferably, the thickness of the LaAlO₃ film 8b may be, for example, at most about 100 nm so that gate threshold voltage (corresponds to horizontal axis of later-described FIG. 8) does not become too high. The Al₂O₃ film (Al₂O₃ atomic layer film) 8c is a cap film that protects the LaAlO₃ film 8b, the Al₂O₃ film 8c covering an entire area of the surface of the LaAlO₃ film 8b. A thickness of the Al₂O₃ film 8c is, for example, about 2 nm, which obtains a protective function. Due to the Al₂O₃ film 8c, the LaAlO₃ film 8b is not exposed to air during manufacturing processes, thereby enabling protection of the LaAlO₃ film 8b from moisture absorption (H₂O absorption).

Further, contamination of the LaAlO₃ film 8b during annealing (POA, or instead of POA, post deposition annealing (PDA), refer to step S8 in later-described FIG. 3) performed after deposition of the Al₂O₃ film 8c may be prevented by the SiO₂ film 8a.

In the trench 7, the gate electrode 9 is provided on the gate insulating film 8 (i.e., on the Al₂O₃ film 8c), so as to be embedded in the trench 7. A material of the gate electrode 9, for example, may be polysilicon (poly-Si), aluminum, etc. The interlayer insulating film 11 is provided on the front surface of the semiconductor substrate 20, covering the gate electrode 9. For example, a barrier metal 12 that prevents diffusion of metal atoms in a direction from the front electrode 14 to the gate electrode 9 may be provided in an entire area of surfaces between the interlayer insulating film 11 and a later-described front electrode 14.

The ohmic electrodes 13 are silicide films provided on the front surface of the semiconductor substrate 20, in contact holes of the interlayer insulating film 11, in ohmic contact with the n⁺-type source region 5 and the p⁺⁺-type contact regions 6 (in an instance in which the p⁺⁺-type contact regions 6 are omitted, instead of the p⁺⁺-type contact regions 6, the p-type base region 4). The ohmic electrodes 13 are electrically connected to the p-type base region 4, the n⁺-type source region 5, and the p⁺⁺-type contact regions 6. The barrier metal 12, the ohmic electrodes 13, and the front electrode 14 function as a source electrode.

The front electrode 14 is provided in substantially an entire area of the front surface of the semiconductor substrate 20, in the active region so as to be embedded in the contact holes of the interlayer insulating film 11. The front electrode 14 is electrically connected to the p-type base region 4, the n⁺-type source region 5, and the p⁺⁺-type contact regions 6, via the ohmic electrodes 13. A back electrode 15 is provided in an entire area of the back surface of the semiconductor substrate 20 (back surface of the n⁺-type starting substrate 21) and is electrically connected to the n⁺-type substrate region 1. The back electrode 15 functions as a drain electrode.

Next, a method of manufacturing the silicon carbide semiconductor device 10 according to the first embodiment is described. FIG. 3 is a flowchart of an outline of the method of manufacturing the silicon carbide semiconductor device according to the first embodiment. First, the n⁺-type starting substrate (starting wafer) 21 containing silicon carbide is prepared. Next, on the front surface of the n⁺-type starting wafer, the epitaxial layers 22 and 23 constituting the n-type buffer region 2 and the n⁻-type drift region 3 are epitaxially grown, and the n-type current spreading region 33 is formed in a surface region of the n⁻-type epitaxial layer 23 by ion implantation. Thereafter, the p-type epitaxial layer 24 constituting the p-type base region 4 is epitaxially grown, whereby the semiconductor substrate (the semiconductor wafer) 20 is formed (step S1).

Next, the n⁺-type source region 5 and the p⁺⁺-type contact regions 6 are each selectively formed in surface regions of the p-type epitaxial layer 24 by ion implantation. A portion of the p-type epitaxial layer 24 excluding the n⁺-type source region 5 and the p⁺⁺-type contact regions 6 is left as is at an impurity concentration of the p-type epitaxial layer 24, as the p-type base region 4 free of ion implantation (step S2). Next, the trench 7 that penetrates through the n⁻-type source region 5 and the p-type base region 4 and reaches the n⁻-type drift region 3 is formed by etching (step S3).

Next, the inner wall of the trench 7 is thermally oxidized, whereby on the surface of the semiconductor substrate 20 in the trench 7, the SiO₂ film 8a constituting the gate insulating film 8 is formed along the inner wall of the trench 7 (step S4: first formation process). The thermal oxidation at step S4, for example, may be performed at a temperature of about 1150 degrees C. under a dry oxygen (O₂) atmosphere. Next, the SiO₂ film 8a is reoxidized, for example, by annealing at a temperature of about 1300 degrees C. under an atmosphere containing nitrogen monoxide or nitrous oxide (step S5: the first formation process).

The thermal oxidation at step S4, for example, may be performed under an atmosphere containing nitrogen monoxide or nitrous oxide. In this instance, the annealing (reoxidation of the SiO₂ film 8a) at step S5 is omitted. By forming the SiO₂ film 8a by thermal oxidation under an atmosphere containing nitrogen monoxide or nitrous oxide, or reoxidation of the SiO₂ film 8a under an atmosphere containing nitrogen monoxide or nitrous oxide, the interface state of the gate insulating film 8 and the semiconductor substrate 20 may be passivated.

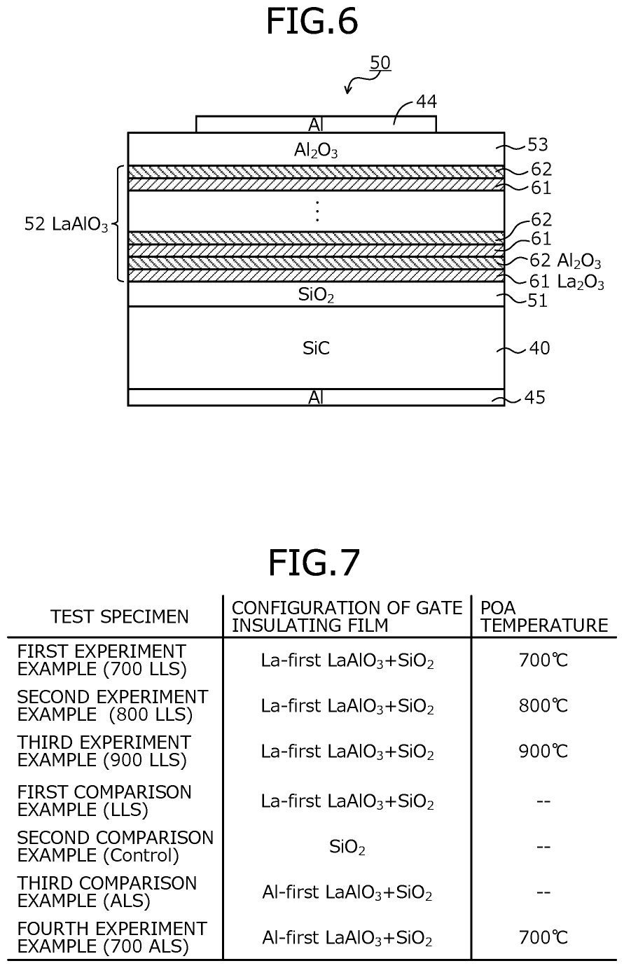

Next, using a ALD method, for example, under an environment of a temperature of about 250 degrees C., a lanthanum oxide (La₂O₃) film (corresponds to La₂O₃ film 61 in later-described FIG. 6, hereinafter, the La₂O₃ film 61) and an aluminum oxide (Al₂O₃) film (corresponds to an Al₂O₃ film (Al₂O₃ atomic layer film) 62 in later-described FIG. 6, hereinafter, the Al₂O₃ film 62) are alternately deposited repeatedly, whereby along the inner wall of the trench 7, on the surface of the SiO₂ film 8a, the lanthanum aluminum oxide (LaAlO₃) film 8b constituting the gate insulating film 8 is formed (step S6: deposition process).

More specifically, in the process at step S6, for example, as a material gas (precursor), a volatile organometallic compound containing lanthanum is injected into a reacting furnace and one atomic layer (layer) of an organometallic compound containing lanthanum is deposited on an outermost surface (outermost surface of the inner wall of the trench 7 and the front surface of the semiconductor substrate 20). Next, residual gas in the reacting furnace is evacuated (purged). Next, water vapor (H₂O) is injected into the reacting furnace, and one atomic layer of oxygen is deposited on a surface of the atomic layer of the organometallic compound containing lanthanum. Next, residual gas in the reacting furnace is evacuated.

Next, as a material gas, a volatile organometallic compound containing aluminum (for example, trimethylaluminum (TMA)) is injected into the reacting furnace, and one atomic layer of an organometallic compound containing aluminum is deposited on an outermost surface (surface of the one atomic layer of oxygen). Next, residual gas in the reacting furnace is evacuated. Next, water vapor is injected into the reacting furnace, and one atomic layer of oxygen is deposited on a surface of the one atomic layer of the organometallic compound containing aluminum. Next, residual gas in the reacting furnace is evacuated. These processes are repeatedly performed until a total thickness of a total atomic layer is a predetermined thickness of the LaAlO₃ film 8b.

One atomic layer of the organometallic compound containing lanthanum and the one atomic layer of oxygen deposited thereon react with each other, whereby the La₂O₃ film 61 is formed. One atomic layer of the organometallic compound containing aluminum and the one atomic layer of oxygen deposited thereon react with each other, whereby the Al₂O₃ film 62 is formed. In evacuating an interior of the reacting furnace, for example, the interior of the reacting furnace is nearly a vacuum. The residual gas evacuated from the reacting furnace contains the precursor (organic matter) decomposed by an oxidation reaction when the La₂O₃ film 61 or the Al₂O₃ film 62 is formed, excess material gas, and excess water.

As a result, the La₂O₃ film 61 and the Al₂O₃ film 62 are alternately deposited on the surface of the SiO₂ film 8a repeatedly, for example, a few hundred times, whereby the LaAlO₃ film 8b is formed by all of these deposited La₂O₃ films 61 and Al₂O₃ films 62. In an instance in which the Al₂O₃ film 62 and the La₂O₃ film 61 are alternately deposited in this order repeatedly, thereby forming the LaAlO₃ film 8b, the process of depositing one atomic layer of the organometallic compound containing lanthanum and the process of depositing one atomic layer of the organometallic compound containing aluminum suffice to be interchanged.

During the process at step S6, either the La₂O₃ film 61 or the Al₂O₃ film 62 may be deposited first; however, it is preferable for the La₂O₃ film 61 to be deposited first (start deposition from the La₂O₃ film 61). A reason for this is that due to contact between the SiO₂ film 8a and the La₂O₃ film 61, the sub-oxide of the surface of the SiO₂ film 8a reacts with lanthanum atoms in the La₂O₃ film 61 and is removed during a subsequent process at step S8. Next, on the surface of the LaAlO₃ film 8b, the Al₂O₃ film 8c that constitutes the gate insulating film 8 is formed (step S7: second formation process).

Next, a POA (or PDA) is performed under an oxygen atmosphere (step S8: heat treatment process). In an instance in which the SiO₂ film 8a and the La₂O₃ film 61 are in contact with each other, during the POA at step S8, the sub-oxide of the surface of the SiO₂ film 8a and the La atoms in the La₂O₃ film 61 react with each other and the oxygen (O) atoms in the sub-oxide are taken into the La₂O₃ film 61, whereby the sub-oxide is cleaned. The sub-oxide of an interface between the SiO₂ film 8a and the La₂O₃ film 61 is removed by the cleaning effect generated by the lanthanum atoms.

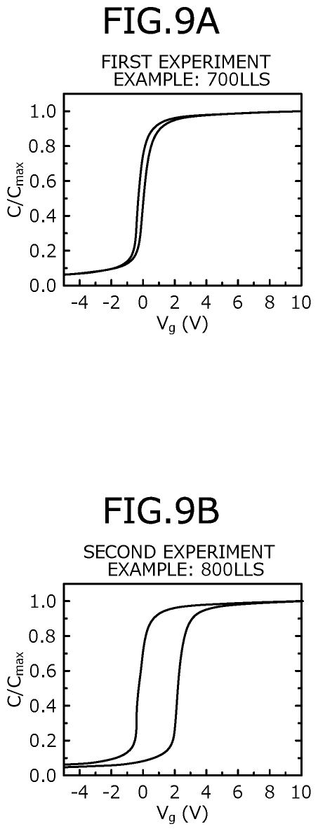

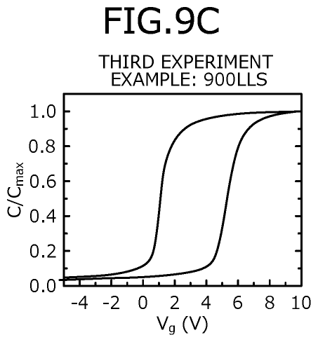

Preferably, a temperature of the POA at step S8 may be, for example, less than 900 degrees C. When the temperature of the POA at step S8 is at least 900 degrees C., lanthanum atoms in the LaAlO₃ film 8b react with the oxygen atoms in the SiO₂ film 8a, and electron trap density in the LaAlO₃ film 8b increases. Due to an increase of the electron trap density in the LaAlO₃ film 8b, hysteresis of a C-V curve of the capacitance C and the gate voltage V g of the gate insulating film 8 increases (refer to later-described FIGS. 9A, 9B, 9C), and the interface state density of the interface between the gate insulating film 8 and the semiconductor substrate 20 increases.

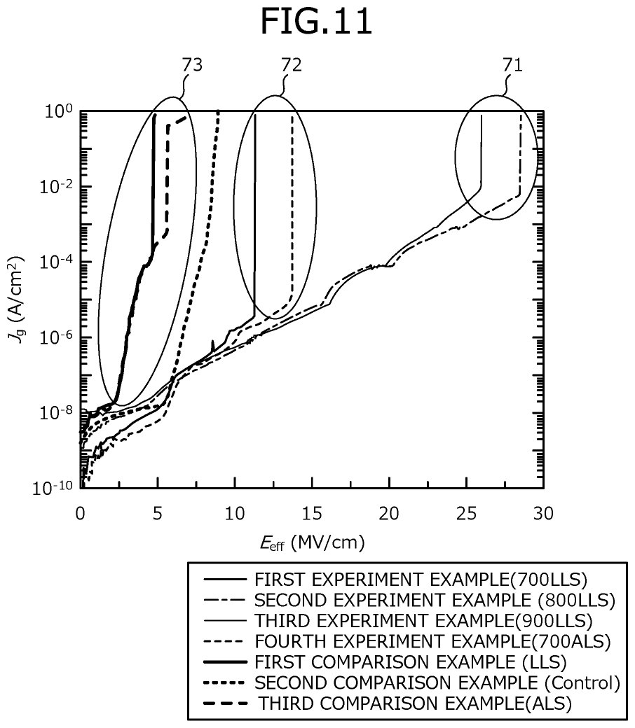

When the interface state density of the interface between the gate insulating film 8 and the semiconductor substrate 20 increases, channel mobility decreases, channel resistance increases, and gate characteristics degrade. When the temperature of the POA at step S8 is, for example, less than 700 degrees C., dielectric breakdown electric field strength E_{eff} of SiC (the semiconductor substrate 20) decreases and therefore, preferably the temperature of the POA at step S8, for example, may be at least about 700 degrees C. For example, by setting the temperature of the POA at step S8 to be at least about 800 degrees C., the dielectric breakdown electric field strength E_{eff} of SiC sufficiently increases (refer to later-described FIG. 11).

On the other hand, the interface state density of the interface between the gate insulating film 8 and the semiconductor substrate 20 increases as the temperature of the POA at step S8 increases. Therefore, to suppress increase of the interface state density of the interface between the gate insulating film 8 and the semiconductor substrate 20, preferably, the temperature of the POA at step S8, for example, may be in a range from about 700 degrees C. to 800 degrees C. (refer to FIGS. 8 to 10). Accordingly, preferably the temperature of the POA at step S8 may be in a temperature range that obtains a predetermined interface state density and a predetermined dielectric breakdown electric field strength E_{eff}, preferably, a range from about 700 degrees C. to 800 degrees C.

Next, the gate electrode 9 is formed on the gate insulating film 8 so as to be embedded in the trench 7 (step S9). By the processes up to here, the MOS gate configured by the trench 7, the gate insulating film 8, and the gate electrode 9 is formed. Next, on the front surface of the semiconductor substrate 20, the interlayer insulating film 11 is formed (step S10). Next, the interlayer insulating film 11 is selectively removed, forming contact holes therein, the n⁺-type source region 5 and the p⁺⁺-type contact regions 6 being exposed in the contact holes.

Next, by a general method, the barrier metal 12 covering an entire area of the surface of the interlayer insulating film 11 is formed. Next, in the contact holes of the interlayer insulating film 11, the ohmic electrodes 13 in ohmic contact with the n⁺-type source region 5 and the p⁺⁺-type contact regions 6 are formed. Next, on both main surfaces of the semiconductor substrate 20, surface electrodes (the front electrode 14 and the back electrode 15) are formed, respectively (step S11). Thereafter, the semiconductor wafer is cut (diced) into individual semiconductor chips, whereby the silicon carbide semiconductor device 10 depicted in FIGS. 1 and 2 is completed.

As described above, according to the first embodiment, the gate insulating film has a multilayer structure including the LaAlO₃ film. As a result, relative permittivity of the gate insulating film may be optimized by the LaAlO₃ film, and electric field applied to the gate insulating film when reverse bias is applied between the gate and source may be mitigated. Therefore, electric field applied to the gate insulating film at the bottom of the trench may be mitigated without disposing a p⁺-type region near the bottom of the trench to mitigate the electric field and the reliability of the gate insulating film may be ensured. Further, a process for forming a p⁺-type region for mitigating electric field may be omitted and therefore, the manufacturing process is simplified and manufacturing cost may be reduced.

Further, according to the first embodiment, in forming the LaAlO₃ film, the La₂O₃ films (atomic layers) and the Al₂O₃ films (atomic layers) are alternately deposited with one another repeatedly using a ALD method. Here, the La₂O₃ film is deposited first, whereby the sub-oxide of the surface of the SiO₂ film is removed by the cleaning effect of the lanthanum atoms in the La₂O₃ film during the POA performed subsequently and the interface state density of the interface between the gate insulating film and the semiconductor substrate may be reduced. The temperature of this POA is suitably set within in a range from 700 degrees C. to less than 900 degrees C., whereby the dielectric breakdown electric field strength of SiC may be increased and increase of the interface state density of the interface between the gate insulating film and the semiconductor substrate may be suppressed.

Alternatively, according to the first embodiment, in forming the LaAlO₃ film using an ALD method, the Al₂O₃ film is deposited first, whereby migration of the La atoms may be prevented and thus, the interface between the SiO₂ and the semiconductor substrate (SiC portion) may be kept in a normal state. As a result, compared to depositing the La₂O₃ atomic layer film first, the interface state density of the interface between the gate insulating film and semiconductor substrate may be reduced and in the CV curve, flat band shift voltage from an ideal curve may be reduced, i.e., fixed charge in the oxide film may be reduced.

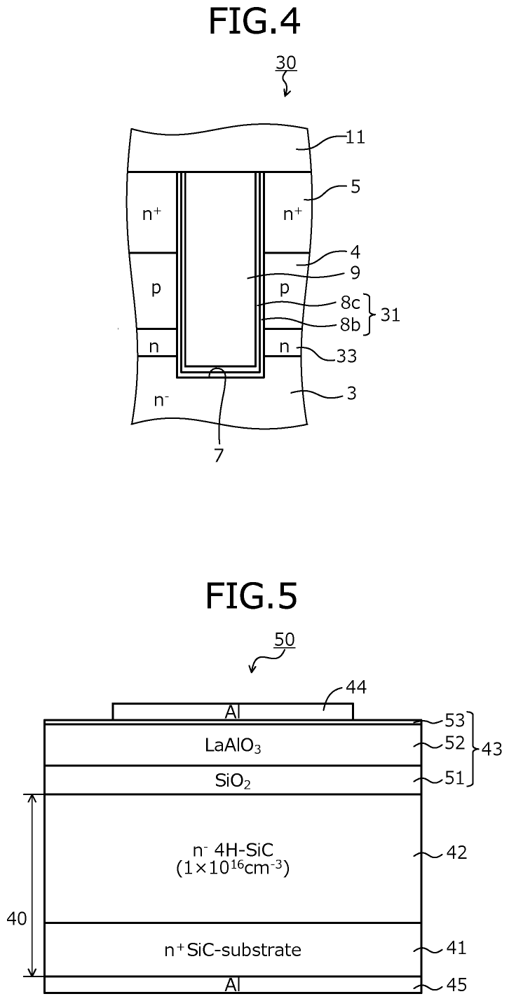

Next, a structure of a silicon carbide semiconductor device according to a second embodiment is described. FIG. 4 is a cross-sectional view of the structure of the silicon carbide semiconductor device according to the second embodiment. FIG. 4 is an enlarged view of a vicinity of the MOS gate. Excluding a gate insulating film 31, configuration of a silicon carbide semiconductor device 30 according to the second embodiment is similar to that depicted in FIG. 1. The silicon carbide semiconductor device 30 according to the second embodiment differs from the silicon carbide semiconductor device 10 according to the first embodiment (refer to FIG. 2) in that only the LaAlO₃ film 8b and the Al₂O₃ film 8c are sequentially stacked as the gate insulating film 31.

In the second embodiment, the gate insulating film 31 has a 2-layer structure including the LaAlO₃ film 8b and the Al₂O₃ film 8c, and is free of a SiO₂ film (corresponds to reference character 8a in FIG. 2). The LaAlO₃ film 8b is in direct contact with the semiconductor substrate 20 at the inner wall of the trench 7. A method of manufacturing the silicon carbide semiconductor device 30 according to the second embodiment may be implemented by the method of manufacturing the silicon carbide semiconductor device 10 according to the first embodiment (refer to FIG. 3) omitting step S4 (formation of the SiO₂ film) and step S5 (reoxidation of the SiO₂ film) therein.

In the second embodiment as well, similarly to the first embodiment, in the process (formation of the LaAlO₃ film 8b by the ALD method) at step S6, it is preferable for the La₂O₃ film 61 (refer to FIG. 6) to be deposited first (i.e., to be in contact with the semiconductor substrate 20). A reason for this is similar to that of the first embodiment, the sub-oxide of the surface of the semiconductor substrate 20 and the La atoms in the La₂O₃ film 61 react during the POA at step S8, and the sub-oxide of an interface between the semiconductor substrate 20 and the La₂O₃ film 61 is removed by the cleaning effect due to the lanthanum, whereby a steep interface with a SiC surface (surface of the semiconductor substrate 20) is formed, enabling reduction of an interface state density of an interface between the gate insulating film 31 and the semiconductor substrate 20.

As described above, according to the second embodiment, even in an instance in which the gate insulating film has a 2-layer structure including the LaAlO₃ film and the Al₂O₃ film, effects similar to those of the first embodiment may be obtained.

The temperature of the POA at step S8 of the method of manufacturing the silicon carbide semiconductor device 10 according to the first embodiment was verified (refer to FIG. 3). FIG. 5 is a cross-sectional view schematically depicting a cross-section of a structure of a MOS capacitor of experiment examples. FIG. 6 is a cross-sectional view schematically depicting a state of a gate electrode and a gate insulating film of the experiment examples during deposition thereof. FIG. 7 is a table showing configurations of the gate insulating films of the experiment examples. FIGS. 8 and 9 are characteristics diagrams depicting, for the experiment examples, relationships between C-V (capacitance C-gate voltage V g of the gate insulating film) characteristics and the temperature of the POA at step S8 in FIG. 3.

MOS capacitors 50 (refer to FIG. 5) having a gate insulating film 43 formed according to the processes at steps S4 to S8 of FIG. 3 described above were prepared (hereinafter, first to third experiment examples). For the first to the third experiment examples, the temperature of the POA at step S8 was 700 degrees C., 800 degrees C., and 900 degrees C., respectively. The MOS capacitors 50 correspond to the MOS gate of the silicon carbide semiconductor device 10 according to the first embodiment in FIGS. 1 and 2, and include a stacked structure (gate stack) in which the gate insulating film 43 and a gate electrode 44 are sequentially stacked on a front surface of a semiconductor substrate 40.

The semiconductor substrate 40 was formed by epitaxially growing an n⁻-type epitaxial layer 42 on an n⁺-type starting substrate 41 containing silicon carbide. A crystalline structure of the semiconductor substrate 40 was a 4-layer periodic hexagonal crystalline structure (4H-SiC). An impurity concentration of the n⁻-type epitaxial layer 42 was 1××10¹⁶/cm³. The semiconductor substrate 40, the n⁺-type starting substrate 41, the n⁻-type epitaxial layer 42, the gate insulating film 43, and the gate electrode 44 respectively correspond to the semiconductor substrate 20, the n⁺-type starting substrate 21, the n⁻-type epitaxial layer 23, the gate insulating film 8, and the gate electrode 9 in FIG. 1.

The gate insulating film 43 had a multilayer structure including a SiO₂ film 51, an LaAlO₃ film 52, and an Al₂O₃ film 53 (respectively corresponding to the SiO₂ film 8a, the LaAlO₃ film 8b, and the Al₂O₃ film 8c in FIG. 2) sequentially stacked on a front surface (main surface having the n⁻-type epitaxial layer 42) of the semiconductor substrate 40. The SiO₂ film 51 was formed by thermally oxidizing the front surface of the semiconductor substrate 40 by a temperature of about 1150 degrees C. under a dry oxygen (O₂) atmosphere. The SiO₂ film 51 was reoxidized by annealing at a temperature of about 1300 degrees C. under a nitrous oxide atmosphere.

The LaAlO₃ film 52 was formed by first depositing the La₂O₃ film 61 in contact with the SiO₂ film 51 and alternately depositing the La₂O₃ film 61 and the Al₂O₃ film 62 repeatedly, using the ALD method in the process at step S6 (refer to FIG. 6). For the LaAlO₃ film 52, the POA at step S8 was performed at a predetermined temperature under a nitrous oxide atmosphere. Thicknesses of the SiO₂ film 51, the LaAlO₃ film 52, and the Al₂O₃ film 53 were 8 nm, 45 nm, and 2 nm, respectively. The gate electrode 44 was an aluminum layer.

The stacked structure of the gate insulating film 43 and the gate electrode 44 depicted in FIGS. 5 and 6 have a flat shape (planar gate structure) along the front surface of the semiconductor substrate 40. In an instance in which the MOS capacitors 50 in FIGS. 5 and 6 are applied to a trench gate structure, the gate insulating film 43 is provided along an inner wall of a trench (refer to the trench 7 in FIGS. 1 and 2), and the gate electrode 44 is provided on the gate insulating film 43 so as to be embedded in the trench. On a back surface of the semiconductor substrate 40, a back electrode 45 (corresponds to the back electrode 15 in FIG. 1) was provided. The back electrode 45 was an aluminum layer.

Configurations of the gate insulating film 43 of the first to the third experiment examples are shown in FIG. 7. As described above, the gate insulating film 43 of the first to the third experiment examples has a multilayer structure in which the SiO₂ film 51, the LaAlO₃ film 52, and the Al₂O₃ film 53 are sequentially stacked (in FIG. 7, indicated as “LaAlO₃+SiO₂”). The LaAlO₃ film 52 of the first to the third experiment examples was formed by first depositing the La₂O₃ film 61 in contact with the SiO₂ film 51 (in FIG. 7, indicated as “La-first”), and alternately depositing the La₂O₃ film 61 and the Al₂O₃ film 62, repeatedly, using the ALD method in the process at step S6.

In FIG. 7, the first to the third experiment examples are respectively indicated as “700LLS”, “800LLS”, and “900LLS”, abbreviations obtained by taking “the temperature of the POA at step S8”, the first letter of “La-first”, and the first letter of each molecular formula “LaAlO₃+SiO₂”. A MOS capacitor having a stacked structure similar to that of the first to the third experiment examples, including a stacked gate insulating film and a gate electrode was prepared as a first comparison example. The first comparison example differs from the first to the third experiment examples in that the POA at step S8 is not performed. In FIG. 7, the first comparison example is indicated as “LLS”.

A general MOS capacitor having a gate insulating film configured by only a SiO₂ film was prepared as a second comparison example. For the second comparison example, the POA at step S8 was omitted. The second comparison example served as an evaluation reference for gate characteristics of the first to the third experiment examples and in FIG. 7, is indicated as “Control”. MOS capacitors having a gate insulating film and a gate electrode stacked on a front surface of a semiconductor substrate containing silicon carbide were prepared as a third comparison example and a fourth experiment example. In the third comparison example and the fourth experiment example, the gate insulating film had a multilayer structure including a SiO₂ film, an LaAlO₃ film, and an Al₂O₃ film sequentially stacked.

The third comparison example and the fourth experiment example differ from the first to the third experiment examples in that in the process at step S6, in forming the LaAlO₃ film using the ALD method, the Al₂O₃ film was deposited first (in FIG. 7, indicated as “Al-first”). For the third comparison example, the POA at step S8 was not performed. For the fourth experiment example, the temperature of the POA at step S8 was 700 degrees C., the fourth experiment example corresponding to another example of the first embodiment. In FIG. 7, the third comparison example and the fourth experiment example are indicated as “ALS (Al-first LaAlO₃+SiO₂)” and “700ALS”, respectively.

For the first to the third experiment examples, C-V curves of the capacitance C and the gate voltage V g of the gate insulating film 43 when the gate voltage V g applied to the gate electrode 44 was swept from +10V to the negative side are depicted in FIG. 8. FIG. 8 depicts, for the first comparison example, the C-V curve of the capacitance C and the gate voltage V g of the gate insulating film when the gate voltage Vg is swept under conditions similar to those of the first to the third experiment examples. In FIG. 8, a horizontal axis is the gate voltage V g and a vertical axis is a ratio of actual measured values (the capacitance C) to a maximum capacitance Cₘₐₓ (=C/Cₘₐₓ) of the gate insulating film 43.

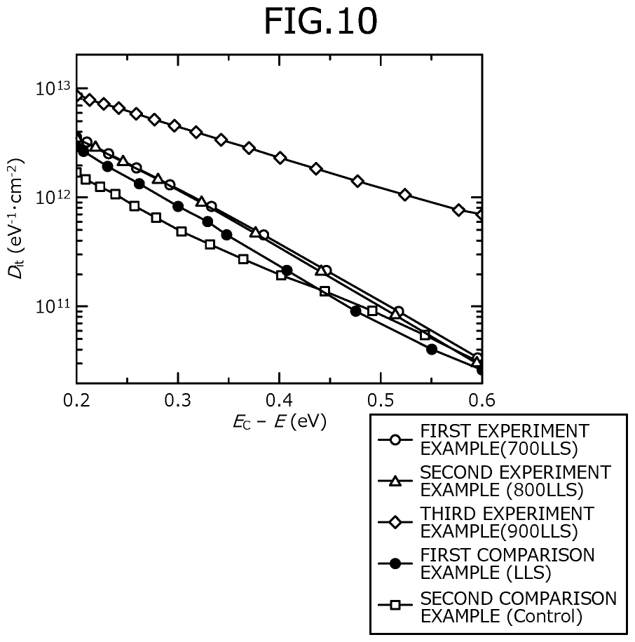

From the results shown in FIG. 8, for the first and the second experiment examples, it was confirmed that C-V characteristics similar to those of the first comparison example for which the POA at step S8 was not performed were obtained. On the other hand, it was confirmed for the third experiment example, the C-V curve shifted about 1V more to the positive side than for the first comparison example, and a negative fixed charge was accumulated in the gate insulating film 43 and an interface between the gate insulating film 43 and the semiconductor substrate 40. A reason for this is that the temperature of the POA at step S8 is high, whereby chemical bonds of the gate insulating film 43 change, and the interface state density of the interface between the gate insulating film 43 and the semiconductor substrate 40 increases (refer to FIG. 10).

Further, for the first to the third experiment examples, the C-V curves of the capacitance C and the gate voltage V g of the gate insulating film 43 when the gate voltage V g applied to the gate electrode 44 was swept from the negative side to +10V (mobile charge is accumulated), and was swept from +10V to the negative side (mobile charge is discharged) are depicted in FIGS. 9A, 9B, and 9C. FIGS. 9A, 9B, and 9C are characteristics diagrams depicting, for the experiment examples, relationships between C-V characteristics and the temperature of the POA at step S8 in FIG. 3. In FIGS. 9A, 9B, and 9C, a horizontal axis and a vertical axis, similar to those of FIG. 8, are the gate voltage V_{g}, and ratios of actual measured values (the capacitance C) to the maximum capacitance Cₘₐₓ of the gate insulating film 43 (=C/Cₘₐₓ).

From the results shown in FIGS. 9A, 9B, and 9C, it was confirmed that for the first experiment example, the C-V curve of the capacitance C and the gate voltage V g of the gate insulating film 43 was in an excellent state with hysteresis (a shift width of the C-V curve during mobile charge accumulation and during mobile charge discharge) being substantially not observed. On the other hand, it was confirmed that like the second and the third experiment examples, the higher the temperature of the POA at step S8 is set, the greater hysteresis of the C-V curve of the capacitance C and the gate voltage V g of the gate insulating film 43 becomes, and mobile charge in the gate insulating film 43 and the interface between the gate insulating film 43 and the semiconductor substrate 40 becomes difficult to discharge.

A reason that mobile charge becomes difficult to discharge in this manner is that trap density of the mobile charge in the gate insulating film 43 and the interface between the gate insulating film 43 and the semiconductor substrate 40 increases the higher the temperature of the POA at step S8 is set. Further, the higher the temperature of the POA at step S8 is set, the chemical bonds of the interface between the gate insulating film 43 and the semiconductor substrate 40 change and effects due to the POA at step S8 are lost. From the results in FIGS. 8 and 9, it was confirmed that it is favorable for the temperature of the POA at step S8 to be less than 900 degrees C.

Measured results of the interface state density of the interface between the gate insulating film 43 and the semiconductor substrate 40 of the first to the third experiment examples are shown in FIG. 10. FIG. 10 is a characteristics diagram depicting relationships between the temperature of the POA at step S8 in FIG. 3 and the interface state density of the interface between the gate insulating film and the semiconductor substrate for the experiment examples. In FIG. 10, a horizontal axis is an energy level (=E_{c}−E) from a bottom of a conduction band of the semiconductor substrate 40 of SiC and a vertical axis is interface state density Dᵢₜ of the interface between the gate insulating film 43 and the semiconductor substrate 40. FIG. 10 further shows results of measurement of the interface state density of the interface between the gate insulating film and the semiconductor substrate of the first and the second comparison examples.

From the results shown in FIG. 10, it was confirmed that for the first and the second experiment examples, increase of the interface state density of the interface between the gate insulating film 43 and the semiconductor substrate 40 is small compared to the first comparison example for which the POA at step S8 was not performed and the second comparison example in which the gate insulating film is configured by only the SiO₂ film, and it was confirmed that the interface state density of the interface between the gate insulating film 43 and the semiconductor substrate 40 is about a same as that in the first and the second comparison examples. On the other hand, it was confirmed for the third experiment example that, increase of the interface state density of the interface between the gate insulating film 43 and the semiconductor substrate 40 becomes large compared to the first and the second comparison examples.

A reason for this is that in the third experiment example, the temperature of the POA at step S8 is high, whereby chemical bonds of the gate insulating film 43 change. When the interface state density of the interface between the gate insulating film 43 and the semiconductor substrate 40 increases, channel mobility decreases, channel resistance increases, and gate characteristics degrade. From the results shown in FIG. 10, it was confirmed that to reduce the interface state density of the interface between the gate insulating film 43 and the semiconductor substrate 40, it is favorable for the temperature of the POA at step S8 to be set to less than 900 degrees C.

Results of measurement of the dielectric breakdown electric field strength E_{eff} of SiC (the semiconductor substrate 40) of the first to the third experiment examples are shown in FIG. 11. FIG. 11 is a characteristics diagram depicting relationships between the dielectric breakdown electric field strength of the experiment examples and the temperature of the POA at step S8 in FIG. 3. In FIG. 11, a horizontal axis is the dielectric breakdown electric field strength E_{eff} and a vertical axis is gate leak current density J_{g} of the gate insulating film 43. The dielectric breakdown electric field strength E_{eff} is calculated by equation (1) below based on the gate voltage V_{g} applied to the gate insulating film 43, a flat band voltage V_{fb} of SiC, and an effective thickness EOT of the gate insulating film 43.

The flat band voltage V_{fb} is a voltage necessary to induce flat band capacitance (=charge q/flat band voltage V_{fb}) to an energy level E_{c} of the bottom of the conduction band of SiC (the semiconductor substrate 40). The effective thickness EOT of the gate insulating film 43 (equivalent oxide thickness) is a thickness obtained by converting the thickness of the gate insulating film 43 including a high permittivity film (the LaAlO₃ film 52) into an electrical thickness equivalent to the gate insulating film including only the SiO₂ film, calculated by equation (2) below.

E_{eff}=(V_{g}−V_{fb})/EOT (1)

EOT=A×ε₀×ε_{SiO2}/Cₘ (2)

In equation (2), “A” is a mathematical area (contact area in contact with the gate insulating film 43) of the gate electrode 44. “ε₀” is permittivity of vacuum. “ε_{SiO2}” is permittivity of SiO₂. “Cₘ” is electrostatic capacitance of the gate insulating film 43 measured quasi-statically assuming the gate voltage V g applied to the gate insulating film 43 to be 10V. FIG. 11 further shows the dielectric breakdown electric field strength E_{eff} of the first to the third comparison examples and the fourth experiment example. Configurations of the third comparison example and the fourth experiment example are respectively similar to those of the first comparison example and the first experiment example, excluding “Al-first” (refer to FIG. 7) during the formation of the LaAlO₃ film.

From the results shown in FIG. 11, it was confirmed that in the second and the third experiment examples, the dielectric breakdown electric field strength E_{eff} (portion surrounded by a frame 71) may be sufficiently increased, and the temperature of the POA at step S8 is favorably at least 800 degrees C. In both the first and the fourth experiment examples for which the temperature of the POA at step S8 was 700 degrees C., it was confirmed that the dielectric breakdown electric field strength E_{eff} (portion surrounded by a frame 72) decreased more compared to the second and the third experiment examples. Reference numeral 73 is the dielectric breakdown electric field strength E_{eff} of the first to the third comparison examples for which the POA at step S8 was not performed.

While not depicted, when the temperature of the POA at step S8 exceeds 700 degrees C. but is less than 800 degrees C., the dielectric breakdown electric field strength E_{eff} varies between the dielectric breakdown electric field strength E_{eff} of the first experiment example and the dielectric breakdown electric field strength E_{eff} of the second experiment example 2. Therefore, if the predetermined dielectric breakdown electric field strength E_{eff} may be obtained, the temperature of the POA at step S8 may be in a range from 700 degrees C. to less than 800 degrees C.

From the results shown in FIGS. 8 to 11, it was confirmed that it is favorable for the temperature of the POA at step S8 to be in range from 700 degrees C. to less than 900 degrees C. Further, from the results shown in FIGS. 8 to 10, it was confirmed that to suppress increase of the interface state density of the interface between the gate insulating film 43 and the semiconductor substrate 40, it is favorable for the temperature of the POA at step S8 to be in a range from about 700 degrees to 800 degrees C. From the results shown in FIG. 11, it was confirmed that to increase the dielectric breakdown electric field strength E_{eff}, it is favorable for the temperature of the POA at step S8 to be at least about 800 degrees C.

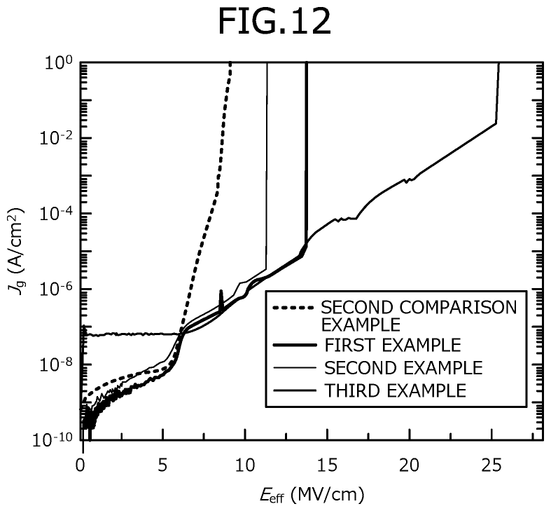

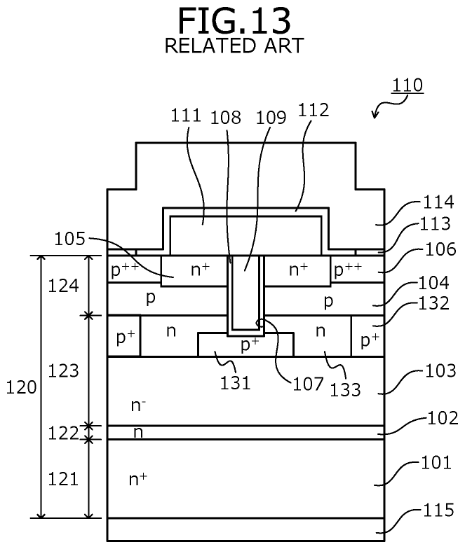

The dielectric breakdown electric field strength E_{eff} of SiC (the semiconductor substrate 20) of the silicon carbide semiconductor device 30 according to the second embodiment (refer to FIG. 4) was verified. FIG. 12 is a characteristics diagram depicting the dielectric breakdown electric field strength of examples. A MOS capacitor (hereinafter, third example) having a MOS gate (the gate insulating film 31 and the gate electrode 9) formed according to the method of manufacturing the silicon carbide semiconductor device 30 according to the second embodiment described above (refer to FIGS. 3 and 4) was prepared. For the third example, results of measurement of the dielectric breakdown electric field strength E_{eff} are shown in FIG. 12.

The third example differs from a later-described first example in that the gate insulating film 31 has a 2-layer structure including the LaAlO₃ film 8b and the Al₂O₃ film 8c, and does not have a SiO₂ film. More specifically, the third example was formed by first depositing the La₂O₃ film 61 in contact with the front surface of the semiconductor substrate 40 using the ALD method in the process at step S6 (i.e., “La-first”), and alternately depositing the La₂O₃ film 61 and the Al₂O₃ film 62 repeatedly. For the third example, the temperature of the POA at step S8 was 700 degrees C.

FIG. 12 further shows results of measurement of the dielectric breakdown electric field strength E_{eff} of MOS capacitors (hereinafter, the first and second examples) having a MOS gate formed according to the method of manufacturing the silicon carbide semiconductor device 10 according to the first embodiment (refer to FIGS. 2 and 3). The first and the second examples respectively correspond to the fourth experiment example (i.e., 700ALS) and the first experiment example (i.e., 700LLS) described above. FIG. 12 further shows results of measurement of the dielectric breakdown electric field strength E_{eff} of the second comparison example having a gate insulating film configured by only a SiO₂ film.

From the results shown in FIG. 12, it was confirmed that for all of the first to the third examples including the LaAlO₃ film 8b in the gate insulating film 8, 31, the dielectric breakdown electric field strength E_{eff} may be set higher compared to the second comparison example having the gate insulating film configured by only the SiO₂ film. For example, in the first example, the dielectric breakdown electric field strength E_{eff} may be enhanced about 50% as compared to the second comparison example. Further, in the first example, it was confirmed that the dielectric breakdown electric field strength E_{eff} becomes high compared to the second example.

In the first example, during the POA at step S8, the Al₂O₃ film 62 between the SiO₂ film 8a and the La₂O₃ film 61 prevents movement of the lanthanum atoms in the La₂O₃ film 61 to the SiO₂ film 8a or prevents movement of the silicon atoms in the SiO₂ film 8a to the LaAlO₃ film 8b (blocking function of the Al₂O₃ film 62). In the second example, the La₂O₃ film 61 is in contact with the SiO₂ film 8a, whereby the blocking function of the Al₂O₃ film 62 becomes low compared to the first example. Therefore, in the first example, the dielectric breakdown electric field strength E_{eff} becomes high compared to the second example.

For the third example, it was confirmed that when the dielectric breakdown electric field strength E_{eff} is at most 5 MV/cm, the gate leak current density becomes high compared to the first and the second examples and the second comparison example. In the third example, the gate leak current density increases when the dielectric breakdown electric field strength E_{eff} is low because band offset of the conduction band between SiC (the semiconductor substrate 20) and the LaAlO₃ film 8b is low. In third example, an effective thickness CET of the gate insulating film 31 is thinnest compared those in the first and the second examples and the second comparison example.

Accordingly, in the third example, compared to the first and the second examples and the second comparison example, the effective thickness CET of the gate insulating film 31 is the thinnest, whereby a dielectric breakdown voltage of the gate insulating film 31 increases and the dielectric breakdown electric field strength E_{eff} of SiC (the semiconductor substrate 20) may be maximized. The effective thickness CET (capacitance equivalent thickness) of the gate insulating film 31 is a thickness that obtains an electrostatic capacitance equivalent to a capacitance compensated for an effect (quantum effect) of the semiconductor substrate 20 and an effect (depletion) of the gate electrode 9.

In the foregoing, the present invention, without limitation to the embodiments described above, may be variously modified within a range not departing from the spirit of the invention. For example, in the embodiments described above, while a MOSFET having a trench gate structure is described, without limitation hereto, instead of the trench gate structure, a planar gate structure may be applied, and instead of the MOSFET, another MOS-type silicon carbide semiconductor device such as insulated gate bipolar transistor (IGBT) may be applied.

In an instance in which the present invention is applied to a planar gate structure, on the front surface (surface of the semiconductor substrate) of the semiconductor substrate, the gate insulating film having the three-layer structure including a SiO₂ film, a LaAlO₃ film, and an Al₂O₃ film sequentially stacked, or the gate insulating film having the 2-layer structure including a LaAlO₃ film and an Al₂O₃ film sequentially stacked suffices to be formed, and the gate electrode suffices to be formed on the gate insulating film. Further, in an instance in which the present invention is applied to an IGBT, instead of the n⁺-type starting substrate constituting the n⁺-type substrate region, a p⁺-type starting substrate constituting a p⁺-type collector region suffices to be used. Further, the present invention is similarly implemented when the conductivity types (n-type, p-type) are reversed.

According to the invention described above, the relative permittivity of the gate insulating film may be increased by the LaAlO₃ film and therefore, when reverse bias is applied between the gate and the source, the electric field applied to the gate insulating film may be mitigated. Further, according to the invention described above, in forming the LaAlO₃ film by alternately depositing a La₂O₃ atomic layer film and an Al₂O₃ atomic layer film repeatedly using the atomic layer deposition method, a La₂O₃ atomic layer film is deposited first, whereby a sub-oxide of the surface of the semiconductor substrate (or the surface of the SiO₂ film) may be removed. As a result, the interface state density of the interface between the gate insulating film and the semiconductor substrate may be reduced. Alternatively, in forming the LaAlO₃ film using the atomic layer deposition method, an Al₂O₃ atomic layer film is deposited first, whereby the interface state density of the interface between the gate insulating film and the semiconductor substrate is reduced and fixed charge in the oxide film may be reduced.

According to the method of manufacturing a silicon carbide semiconductor device according to the present invention, an effect is achieved in that reliability of the gate insulating film may be ensured.

As described above, the method of manufacturing a silicon carbide semiconductor device according to the present invention is useful for power semiconductor devices used in power converting equipment, power supply devices such as in various types of industrial machines, etc. and is particularly suitable for SiC-MOSFETs having a trench gate structure.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a silicon carbide semiconductor device including an insulated gate having a three-layer structure including a gate electrode, a gate insulating film having a multilayer structure including a LaAlO₃ film, and a semiconductor substrate containing silicon carbide, the method comprising:
forming the gate insulating film on a surface of the semiconductor substrate, the forming the gate insulating film including
repeatedly depositing a La₂O₃ atomic layer film alternating with an Al₂O₃ atomic layer film, wherein the La₂O₃ atomic layer film is deposited first, using an atomic layer deposition method, as a deposition process, thereby forming the LaAlO₃ film as the gate insulating film, and
performing a heat treatment at a temperature that is less than 900 degrees C. after the deposition process; and
forming the gate electrode facing the semiconductor substrate with the gate insulating film intervening therebetween.

2. The method of manufacturing the silicon carbide semiconductor device according to claim 1, wherein
the forming the gate insulating film further includes, before the deposition process, forming, as a part of the gate insulating film, a SiO₂ film in direct contact with the surface of the semiconductor substrate, and
in the deposition process, the LaAlO₃ film is formed on the SiO₂ film, whereby the gate insulating film, including the SiO₂ film and the LaAlO₃ film, is formed.

3. The method of manufacturing the silicon carbide semiconductor device according to claim 1, wherein
in the deposition process, the LaAlO₃ film is formed in direct contact with the surface of the semiconductor substrate.

4. The method of manufacturing the silicon carbide semiconductor device according to claim 1, wherein
the forming the gate insulating film further includes, after the deposition process but before the heat treatment process, forming, as a part of the gate insulating film, an Al₂O₃ film on the LaAlO₃ film.

5. The method of manufacturing the silicon carbide semiconductor device according to claim 1, wherein
the heat treatment is performed under a gas atmosphere containing oxygen.

6. The method of manufacturing the silicon carbide semiconductor device according to claim 1, wherein
the temperature of the heat treatment is at least 700 degrees C.

7. The method of manufacturing the silicon carbide semiconductor device according to claim 1, wherein
the temperature of the heat treatment is at most 800 degrees C.

8. The method of manufacturing the silicon carbide semiconductor device according to claim 2, wherein
the forming the SiO₂ film includes:
forming a first SiO₂ film by thermally oxidizing the surface of the semiconductor substrate under a gas atmosphere containing oxygen, and
reoxidizing the first SiO₂ film under a gas atmosphere containing nitrogen monoxide or nitrous oxide, thereby forming a second SiO₂ film as the part of the gate insulating film.

9. The method of manufacturing the silicon carbide semiconductor device according to claim 2, wherein
the forming the SiO₂ film includes thermally oxidizing the surface of the semiconductor substrate under a gas atmosphere containing nitrogen monoxide or nitrous oxide.

10. A method of manufacturing a silicon carbide semiconductor device including an insulated gate having a three-layer structure including a gate electrode, a gate insulating film having a multilayer structure including a LaAlO₃ film, and a semiconductor substrate containing silicon carbide, the method comprising:
forming the gate insulating film on a surface of the semiconductor substrate, the forming the gate insulating film including
repeatedly depositing an Al₂O₃ atomic layer film alternating with a La₂O₃ atomic layer film, wherein the Al₂O₃ atomic layer film is deposited first, using an atomic layer deposition method, as a deposition process, thereby forming the LaAlO₃ film as the gate insulating film, and
performing a heat treatment at a temperature less than 900 degrees C. after the deposition process; and
forming the gate electrode facing the semiconductor substrate with the gate insulating film intervening therebetween.
